(19) United States
(12) Patent Application Publication
(10) Pub. No.: US 2004/0072445 A1
(43) Pub. Date: Apr. 15, 2004

(54) Effective method to improve surface finish in electrochemically assisted CMP

(75) Inventors: Lizhong Sun, San Jose, CA (US); Feng Q. Liu, San Jose, CA (US); Siew S. Neo, Santa Clara, CA (US); Yan Wang, Sunnyvale, CA (US); Stan D. Tsai, Fremont, CA (US); Liang-Yuh Chen, Foster City, CA (US)

Correspondence Address: Patent Counsel, APPLIED MATERIALS, INC., P.O. Box 450A, Santa Clara, CA, 95052, US

(73) Assignee: APPLIED MATERIALS, INC.

(21) Appl. No.: 10/611,805

(22) Filed: Jun. 30, 2003

Related U.S. Application Data
(60) Provisional application No. 60/395,768, filed on Jul. 11, 2002.

(51) Int. Cl. H01L 21/302; H01L 21/461

(52) U.S. Cl. 438/710

(57) ABSTRACT

The present invention generally is directed to a method of electrochemically and mechanically planarizing a surface of a substrate, comprising: providing a basin containing an electrically conductive solution and an electrode disposed therein, disposing a polishing medium in the electrically conductive solution, positioning a substrate against the polishing medium so that a surface of the substrate contacts the electrically conductive solution, applying a first potential between the polishing medium and the electrode for a first time period, and applying a second potential between the polishing medium and the electrode for a second time period.

### CROSS-REFERENCE TO RELATED APPLICATIONS

This application claims benefit of U.S. provisional patent application serial No. 60/395,768, filed Jul. 11, 2002, which is herein incorporated by reference.

### BACKGROUND OF THE INVENTION

1. Field of the Invention

The invention generally relates to polishing, planarization, plating and combinations thereof. More particularly, the invention relates to electrochemical mechanical polishing and electropolishing.

2. Description of the Related Art

Sub-quarter micron multi-level metallization is one of the key technologies for the next generation of ultra large-scale integration (ULSI). The multilevel interconnects that lie at the heart of this technology require planarization of interconnect features formed in high aspect ratio apertures, including contacts, vias, trenches and other features. Reliable formation of these interconnect features is very important to the success of ULSI and to the continued effort to increase circuit density and quality on individual substrates and die.

In the fabrication of integrated circuits and other electronic devices, multiple layers of conducting, semiconducting, and dielectric materials are deposited on or removed from a surface of a substrate. Thin layers of conducting, semiconducting, and dielectric materials may be deposited by a number of deposition techniques. Common deposition techniques in modern processing include physical vapor deposition (PVD), also known as sputtering, chemical vapor deposition (CVD), plasma-enhanced chemical vapor deposition (PECVD), and electrochemical plating (ECP).

As layers of materials are sequentially deposited and removed, the uppermost surface of the substrate may become non-planar across its surface and require planarization. An example of non-planar process is the deposition of copper films with the ECP process in which the copper topography simply follows the already existing non-planar topography of the wafer surface, especially for lines wider than 10 =l microns. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization is also useful in forming features on a substrate by removing excess deposited material used to fill the features and to provide an even surface for subsequent levels of metallization and processing.

Chemical mechanical planarization, or chemical mechanical polishing (CMP), is a common technique used to planarize substrates. CMP utilizes a chemical composition, typically a slurry or other fluid medium, for selective removal of materials from substrates. In conventional CMP techniques, a substrate carrier or polishing head is mounted on a carrier assembly and positioned in contact with a polishing pad in a CMP apparatus. The carrier assembly provides a controllable pressure to the substrate, thereby pressing the substrate against the polishing pad. The pad is moved relative to the substrate by an external driving force. The CMP apparatus affects polishing or rubbing movements between the surface of the substrate and the polishing pad while dispersing a polishing composition to affect chemical activities and/or mechanical activities and consequential removal of materials from the surface of the substrate.

Another planarization technique is electrochemical mechanical polishing (ECMP). ECMP techniques remove conductive materials from a substrate surface by electrochemical dissolution while concurrently polishing the substrate with reduced mechanical abrasion compared to conventional CMP processes. The electrochemical dissolution is performed by applying a bias between a cathode and a substrate surface to remove conductive materials from the substrate surface into a surrounding electrolyte. Typically, the bias is applied by a ring of conductive contacts to the substrate surface in a substrate support device, such as a substrate carrier head. Mechanical abrasion is performed by positioning the substrate in contact with conventional polishing pads and providing relative motion there between.

A passivation layer is generally formed over the conductive materials to ensure that polishing occurs primarily where contact is made between the conductive materials and a polishing pad. A series of side cross-sectional views of a substrate 113 and a polishing medium 105 illustrating a polishing cycle will now be described with reference to FIGS. 4A-C. Referring first to FIG. 4A, a side view of the substrate 113 and the polishing medium 105 is shown. The polishing medium 105 is shown submerged in the electrolyte 120, which is made an ionic conductor by application of a voltage or current from the power supply 302. The substrate 113 is shown located over the electrolyte 120 and moving downward toward the polishing medium 105. In general, the substrate 113 includes a base material 402 (typically made of silicon) having features formed therein. The base material 402 may be covered by multiple layers of dielectric materials, semiconducting materials and conducting materials. The outermost metal layer 406 has been previously deposited in the features 404 and over the previous dielectric, semiconducting and conductive layers. Illustratively, the metal layer 406 is copper. A passivation layer (which may act as a corrosion inhibitor) 408 is formed over the metal layer 406. The passivation layer 408 is selected to ensure that polishing occurs primarily where contact is made with the polishing medium 105. Passivation agents which are part of the conductive electrolyte will passivate the recess areas of the incoming metal layer to be polished. Illustrative passivation agents include BTA, TTA, etc. Accordingly, as shown in FIG. 4B, the passivation layer 408 is reduced (by polishing) at the interface of the polishing medium 105 and the metal layer 406. The polishing which occurs in FIG. 4B is a combination of mechanical polishing (as a result of relative movement between the substrate 113 and the polishing medium 105) and electrochemical dissolution (as a result of chemical interaction between the substrate 113 and the electrolyte 120).

Polishing continues until the excess bulk metal has been removed. FIG. 4C is illustrative of a surface condition of the substrate 113 at a polishing endpoint. Copper lines (i.e., the copper in the features 404) are not being polished due to the fact that they are protected by the passivation agent and they are not in contact with the polishing medium 105.

Often times, however, the passivation layer is inefficiently removed prior to electrochemical dissolution, which may cause a non-uniform localized current at the substrate surface. This non-uniform localized current, in turn, may cause “burn marks” in the resulting conductive materials formed within the features. These “burn marks” may adversely affect the surface roughness and interconnectivity characteristic of the conductive materials.

Therefore, there is a need for an improved method and apparatus for removing conductive materials from a substrate surface using ECMP techniques.

### SUMMARY OF THE INVENTION

The present invention generally is directed to a method of electrochemically and mechanically planarizing a surface of a substrate, comprising: providing a basin containing an electrically conductive solution and an electrode disposed therein, disposing a polishing medium in the electrically conductive solution, positioning a substrate against the polishing medium so that a surface of the substrate contacts the electrically conductive solution, applying a first potential between the polishing medium and the electrode for a first time period, and applying a second potential between the polishing medium and the electrode for a second time period.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is an electrochemical mechanical polishing (ECMP) station in accordance with an embodiment of the invention;

FIG. 2 is a top view of a polishing medium in accordance with an embodiment of the invention;

FIG. 3 illustrates a polishing station in accordance with an embodiment of the invention;

FIGS. 4A-4C illustrates a polishing cycle in accordance with an embodiment of the invention;

FIGS. 5-8 and 10-15 illustrate various patterns for a time-varying voltage signal in accordance with an embodiment of the invention;

FIGS. 9A-9B illustrate various waveforms for the time-varying voltage signal in accordance with an embodiment of the invention; and

FIG. 16 illustrates a polishing station with an endpoint detection mechanism in accordance with another embodiment of the invention.

### DETAILED DESCRIPTION OF THE PREFERRED EMBODIMENT

The words and phrases used herein should be given their ordinary and customary meaning in the art by one skilled in the art unless otherwise further defined. Chemical-mechanical polishing should be broadly construed and includes, but is not limited to, abrading a substrate surface by chemical activity, mechanical activity, or a combination of both chemical and mechanical activity. Electropolishing should be broadly construed and includes, but is not limited to, planarizing a substrate by the application of electrochemical activity, such as by electrochemical dissolution.

Electrochemical mechanical polishing (ECMP) should be broadly construed and includes, but is not limited to, planarizing a substrate by the application of electrochemical activity, chemical activity, mechanical activity, or a combination of electrochemical, chemical, and mechanical activity to remove material from a substrate surface.

Electrochemical mechanical plating process (ECMP) should be broadly construed and includes, but is not limited to, electrochemically depositing material on a substrate and generally planarizing the deposited material by the application of electrochemical activity, chemical activity, mechanical activity, or a combination of electrochemical, chemical, and mechanical activity.

Electrochemical dissolution should be broadly construed and includes, but is not limited to, the application of a bias to a substrate directly or indirectly which results in the removal of conductive material from a substrate surface and into a surrounding electrolyte solution.

A polishing surface is broadly defined as the portion of an article of manufacture that at least partially contacts a substrate surface during processing or electrically couples an article of manufacture to a substrate surface either directly through contact or indirectly through an electrically conductive medium.

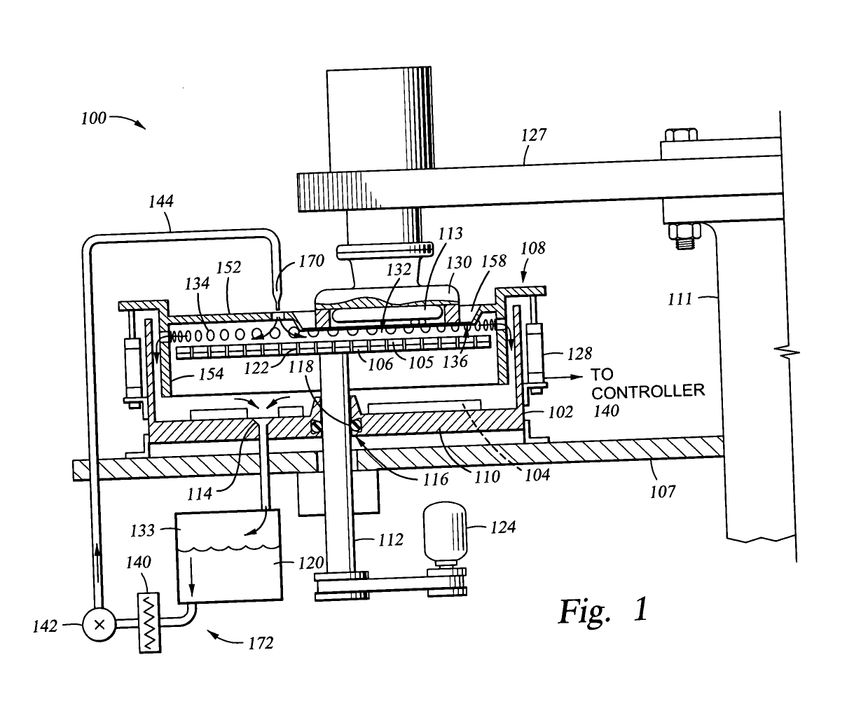

Referring now to FIG. 1, an electrochemical mechanical polishing (ECMP) station 100, which may be a component of a larger platform or tool, is illustrated in accordance with an embodiment of the invention. One polishing tool that may be adapted to benefit from the invention is a MIRRA® chemical mechanical polisher available from Applied Materials, Inc. located in Santa Clara, Calif.

Generally, the electrochemical mechanical polishing (ECMP) station 100 includes a polishing head 130 adapted to retain the substrate 113. Illustratively, the polishing head 130 is a cantilever mounted to a carousel 111 by a brace 127. The carousel 111 operates to rotate the polishing head 130 to a position over various stations, including the ECMP station 100. Examples of embodiments of polishing heads 130 that may be used with the polishing apparatus 100 described herein are described in U.S. Pat. No. 6,024,630, issued Feb. 25, 2000 to Shendon, et al. One particular polishing head that may be adapted to be used is a TITAN HEAD™ wafer carrier, manufactured by Applied Materials, Inc., located in Santa Clara, Calif.

The ECMP station 100 further includes a basin 102, an electrode 104, polishing medium 105, a pad support disc 106 and a cover 108. In one embodiment, the basin 102 is coupled to a base 107 of the polishing apparatus 100. The basin 102, the cover 108, and the disc 106 may be movably disposed relative to the base 107. Accordingly, the basin 102, cover 108 and disc 106 may be axially moved toward the base 107 to facilitate clearance of the polishing head 130 as the carousel 111 indexes the substrate 113 between the ECMP 100 and other polishing stations (not shown).

The basin 102 generally defines a container or electrolyte-containing volume 132 in which a conductive fluid such as an electrolyte 120 (shown in a reservoir 133) can be confined and in which the electrode 104, polishing medium 105, and disc 106 are generally housed. The electrolyte 120 used in processing the substrate 113 in combination with the electrical potential applied to the polishing medium can electrochemically remove metals such as copper, aluminum, tungsten, gold, silver or other conductive materials. Accordingly, the basin 102 can be a bowl-shaped member made of a plastic such as fluoropolymers, TEFLON®, PFA, PE, PES, or other materials that are compatible with electroplating and electropolishing chemistries.

The basin 102 has a bottom 110 that includes an aperture 116 and a drain 114. The aperture 116 is generally disposed in the center of the bottom 110 and allows a shaft 112 to pass therethrough. A seal 118 is disposed between the aperture 116 and the shaft 112 and allows the shaft 112 to rotate while preventing fluids disposed in the basin 102 from passing through the aperture 116. Rotation is imparted to the shaft 112 by a motor connected to a lower end of the shaft 112. The motor may be an actuator capable of rotating the shaft at a predefined speed or speeds.

At an upper end, the shaft 112 carries the disc or pad support 106. The pad support disc 106 provides a mounting surface for the polishing medium 105, which may be secured to the disc 106 by a clamping mechanism or an adhesive (such as a pressure sensitive adhesive). Although shown connected to the shaft 112, in another embodiment, the disc 106 can be secured in the basin 102 using fasteners such as screws or other fastening means, thereby eliminating the need for the shaft 112. The disc 106 can be spaced from the electrode 104 to provide a better electrolyte recirculation.

In one embodiment, the disc 106 may be made from a material compatible with the electrolyte 120 that would not detrimentally affect polishing. Illustratively, the disc 106 may be fabricated from a polymer, for example fluoropolymers, PE, TEFLON®, PFA, PES, HDPE, UHMW or the like. In one embodiment, the disc 106 includes a plurality of perforations or channels formed therein. The perforations are coupled to the perforations of the polishing medium 105 which, cooperatively, define channels 122 extending from a lower surface of the disc 106 to an upper surface of the polishing medium 105. The provision of the channels 122 makes the disc 106 and the polishing medium 105 generally permeable to the electrolyte 120. The perforation size and density is selected to provide uniform distribution of the electrolyte 120 through the disc 106 to the substrate 113.

The polishing medium 105 can be a pad, a web or a belt of material, which is compatible with the fluid environment and the processing specifications. The polishing medium 105 is positioned at an upper end of the basin 102 and supported on its lower surface by the disc 106. In one embodiment, the polishing medium 105 includes at least a partially conductive surface of a conductive material for contact with the substrate surface during processing. Accordingly, the polishing medium 105 may be a conductive polishing material or a composite of a conductive polishing material disposed in a conventional polishing material. The conductive material may also be inserted between the disc 106 and polishing material 105 with some conductive ends for contact with the substrate during polishing. The conductive polishing materials and the conventional polishing materials generally have mechanical properties which do not degrade under sustained electric fields and are resistant to degradation in acidic or basic electrolytes.

The conductive polishing material may include conductive polymers, polymer composites with imbedded conductive materials, conductive metals, conductive fillers or conductive doping materials, or combinations thereof. Conductive polymers include polymeric materials that are intrinsically conductive, such as polyacetylene, polyethylenedioxythiophene (PEDT), which is commercially available under the trade name Baytron™, polyaniline, polypyrrole, and combinations thereof.

The polymer composites with conductive materials may include polymer-noble metal hybrid materials. Polymer-noble metal hybrid materials that may be used as the conductive polishing material described herein are generally chemically inert with a surrounding electrolyte, such as those with noble metals, which are resistant to oxidation. An example of a polymer-noble metal hybrid material is a platinum-polymer hybrid material. The invention contemplates the use of polymer-noble metal hybrid materials, which are chemically reactive with a surrounding electrolyte, when the polymer-noble metal hybrid material is insulated from a surrounding electrolyte by another material.

Conductive metals that may be used as the polishing material are those metals that are relatively inert to chemical reactions with the surrounding electrolyte. Titanium is an example of a conductive metal that may be used as the polishing material. The conductive metals may form a portion or the entire polishing surface of the polishing material. When forming a portion of the polishing surface, the conductive metals are typically disposed in a conventional polishing material.

The conductive polishing materials may further include conductive fillers or conductive doping materials disposed in a binder material, such as the conductive polymers described above or a conventional polishing material. Examples of conductive fillers include carbon powder, carbon fibers, carbon nanotubes, carbon nanofoam, carbon aerogels, and combinations thereof. Carbon nanotubes are conductive hollow filaments of carbon material having a diameter in the nanometer size range. The conductive fillers or conductive doping materials are disposed in the binding material in an amount sufficient to provide a polishing medium having a desired conductivity. The binder material is typically a conventional polishing material.

Conventional polishing materials may include polymeric materials, such as polyurethane, polycarbonate, polyphenylene sulfide (PPS), or combinations thereof, and other polishing materials used in polishing substrate surfaces. An exemplary conventional material includes those found in the IC series of polishing media, for example polyurethane and polyurethane mixed with fillers, commercially available from Rodel Inc., of Phoenix, Ariz. The invention further contemplates the use of other conventional polishing materials, such as a layer of compressible material. The compressible material includes a conventional soft material, such as compressed felt fibers leached with urethane.

In one application, the conductive polishing material or the composite of the conductive polishing material and conventional polishing material are provided to produce a conductive polishing medium having a bulk resistivity of about 10 Ωcm or less or a surface resistivity of about 10 Ω/Square or less. In one aspect, the polishing medium has a resistivity of about 1 Ωcm or less. An example of the conductive polishing material is a layer of platinum, which has a resistivity 9.81 μΩcm at 0° C., disposed on a layer of polyurethane.

The composite of the conductive polishing material and conventional polishing material may include between about 5 wt. % and about 60 wt. % of conductive polishing material in the polishing medium 105. An example of a composite of the conductive polishing material and conventional polishing material includes carbon fibers or carbon nanotubes, disposed in a conventional polishing material of polycarbonate or polyurethane in sufficient amounts to provide a polishing medium having a bulk resistivity of about 10 Ωcm or less and a surface resistivity of about 10 Ω/Square or less.

Further, the invention contemplates the use of abrasive materials embedded in the conventional polishing material. In such an embodiment, the fixed abrasive particles generally include conductive abrasive materials.

Alternatively, the polishing medium 105 may include a metal mesh disposed in the conventional polishing material. The metal mesh may include a chemically inert conductive material, such as platinum. The metal mesh may also include materials that have been observed to react with the surrounding electrolyte, such as copper, if the metal mesh is chemically insulated from the electrolyte such as by a conformal layer of conventional material.

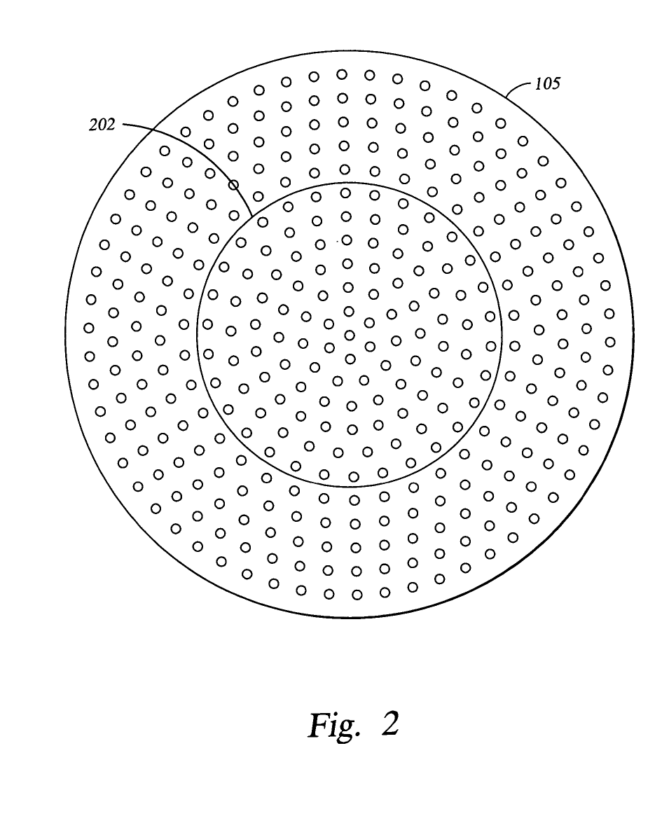

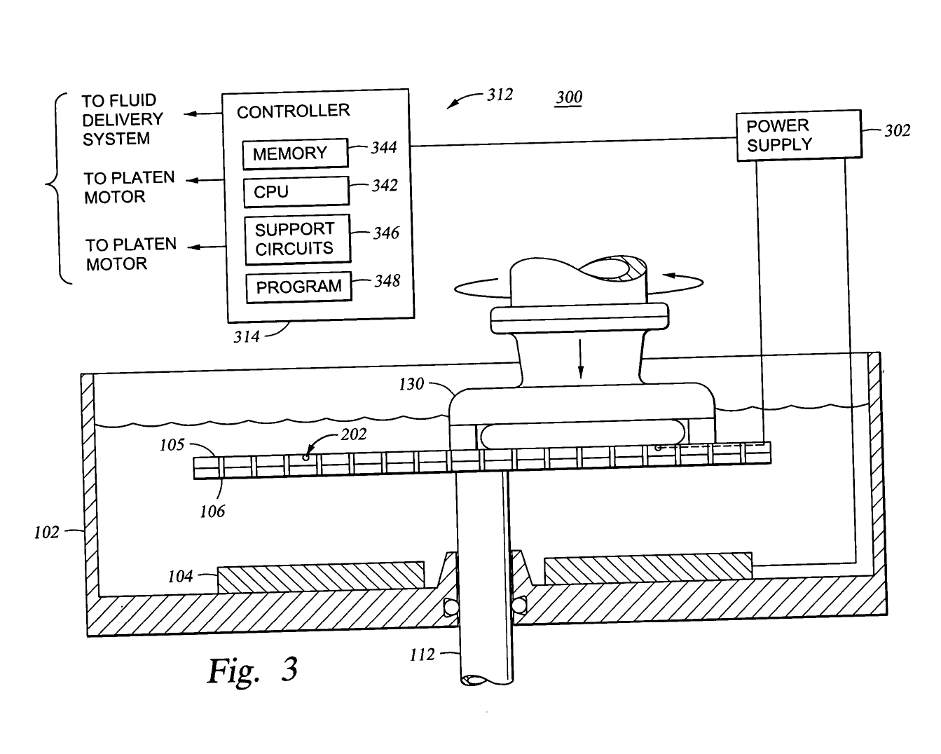

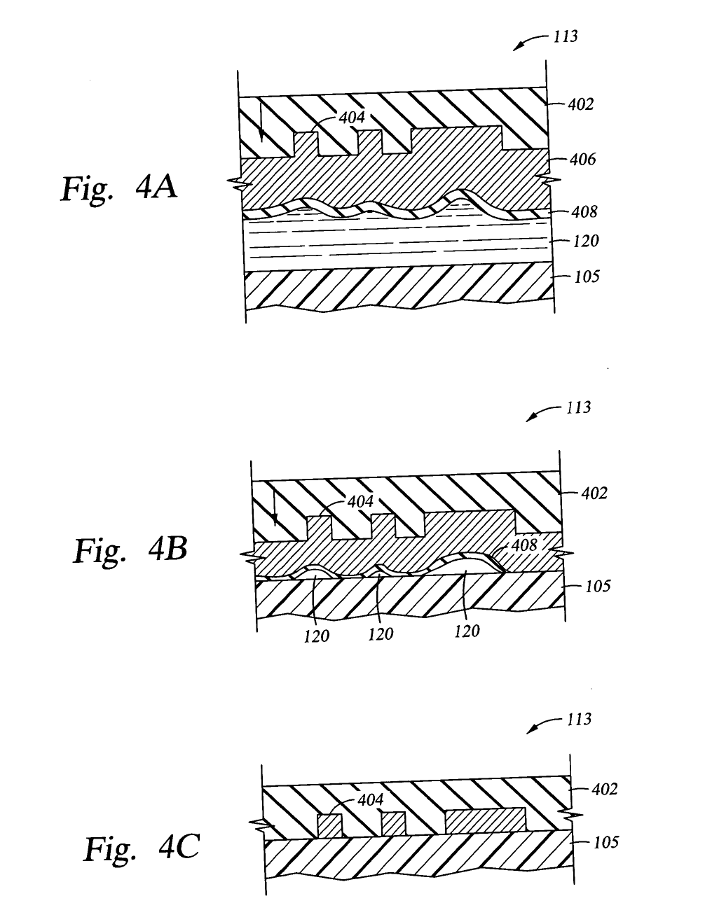

Referring briefly to FIG. 2, a particular illustrative embodiment of the polishing medium 105 is shown from a top view. Generally, the polishing medium 105 is a perforated disc-shaped pad having a conducting element 202 disposed on an upper polishing surface. Illustratively, the conducting element 202 is an annular member disposed about a central axis of the polishing medium 105. More generally, however, the conducting element 202 may be any shape. Further, the conducting element 202 need not be a singular member, but may be a plurality of integrated conducting members, as in the case of the metal mesh described above. The location and size of the conducting element 202 is selected to insure contact between the element 202 and a substrate (e.g., substrate 113) regardless of the position of the substrate on the polishing medium 105.

Because the polishing medium 105 is at least partially conductive, the polishing medium 105 may act as an electrode in combination with the substrate during electrochemical processes. Referring to FIG. 1, the electrode 104 is a counter-electrode to the polishing medium 105 contacting a substrate surface. The electrode 104 may be an anode or cathode depending upon the positive bias (anode) or negative bias (cathode) applied between the electrode 104 and polishing medium 105.

For example, depositing material from an electrolyte on the substrate surface, the electrode 104 acts as an anode and the substrate surface and/or polishing medium 105 acts as a cathode. When removing material from a substrate surface, such as by dissolution from an applied bias, the electrode 104 functions as a cathode and the substrate surface and/or polishing medium 105 may act as an anode for the dissolution process.

The electrode 104 is generally positioned between the disc 106 and the bottom 110 of the basin 102 where it may be immersed in the electrolyte 120. The electrode 104 can be a plate-like member, a plate having multiple holes formed therethrough or a plurality of electrode pieces disposed in a permeable membrane or container. A permeable membrane (not shown) may be disposed between the disc 106 and the electrode 104 to prevent particles or sludge from being released from the electrode 104 into the electrolyte. The permeable membrane may also act as a filter and prevent gas evolution from the counter electrode from reaching the substrate during processing. Pores size and density of the permeable membrane are defined in a way to optimize the process performances. In one embodiment, the permeable membrane is hydophylic.

In operation, the polishing medium 105 is disposed on the disc 106 in an electrolyte in the basin 102. A substrate 113 on the polishing head is disposed in the electrolyte and contacted with the polishing medium 105. Electrolyte is flowed through the perforations of the disc 106 and the polishing medium 105 and is distributed on the substrate surface by grooves 122 formed therein. Power from a power source is then applied to the conductive polishing medium 105 and the electrode 104. In one embodiment to transfer power to a rotating member such as the conductive polishing medium 105 a rotating electrical connection (not shown), generally described in the art as a slip ring, can be used. A slip ring can be purchased from such manufacturers as IDM Electronics LTD, Reading Berkshire, England, a division of Kaydon Corporation, Ann Arbor, Mich. Conductive material, such as copper, on the substrate surface immersed in the electrolyte is then removed by an electrochemical dissolution method.

The electrolyte 120 is flowed from a reservoir 133 into the volume 132 via a nozzle 170. The electrolyte 120 is prevented from overflowing the volume 132 by a plurality of holes 134 disposed in a skirt 154. The holes 134 generally provide a path through the cover 108 for the electrolyte 120 exiting the volume 132 and flowing into the lower portion of the basin 102. At least a portion of the holes 134 are generally positioned between a lower surface 136 of the depression 158 and the center portion 152. As the holes 134 are typically higher than the lower surface 136 of the depression 158, the electrolyte 120 fills the volume 132 and is thus brought into contact with the substrate 113 and polishing medium 105. Thus, the substrate 113 maintains contact with the electrolyte 120 through the complete range of relative spacing between the cover 108 and the disc 106.

The electrolyte 120 collected in the basin 102 generally flows through the drain 114 disposed at the bottom 110 into the fluid delivery system 172. The fluid delivery system 172 typically includes the reservoir 133 and a pump 142. The electrolyte 120 flowing into the fluid delivery system 172 is collected in the reservoir 133. The pump 142 transfers the electrolyte 120 from the reservoir 133 through a supply line 144 to the nozzle 170 where the electrolyte 120 is recycled through the ECMP station 102. A filter 140 is generally disposed between the reservoir 133 and the nozzle 170 to remove particles and agglomerated material that may be present in the electrolyte 120.

Electrolyte solutions may include commercially available electrolytes. For example, in copper containing material removal, the electrolyte may include sulfuric acid, sulfuric acid salt-based electrolytes or phosphoric acid, phosphoric acid salt-based electrolytes, such as potassium phosphate (KₓPO₄, where x=1, 2 or 3), (NH₄)H₂PO₄, (NH₄)₂HPO₄, or combinations thereof. The electrolyte may also contain derivatives of sulfuric acid based electrolytes, such as copper sulfate, and derivatives of phosphoric acid based electrolytes, such as copper phosphate. Electrolytes having perchloric acid-acetic acid solutions and derivatives thereof may also be used. In one embodiment, about 1 to 2 percent of the electrolyte solution is an oxidizer. Additionally, the invention contemplates using electrolyte compositions conventionally used in electroplating or electropolishing processes, including conventionally used electroplating or electropolishing additives, such as brighteners, suppressers, and levelers, among others. One source for electrolyte solutions used for electrochemical processes such as copper plating, copper electrochemical dissolution, or combinations thereof is Shipley Leonel, a division of Rohm and Haas, headquartered in Philadelphia, Pa., under the trade name Ultrafill 2000. An example of a suitable electrolyte composition is described in U.S. patent application Ser. No. 10/038,066, filed on Jan. 3, 2002, which is incorporated by reference to the extent not inconsistent with the aspects and claims herein.

When using mechanical abrasion in the polishing process, the substrate 113 and the polishing medium 105 are rotated relative to one another to remove material from the substrate surface. Mechanical abrasion may be provided by physical contact with both conductive polishing materials and conventional polishing materials as described herein. The substrate 113 and the polishing medium 105 are respectively rotated at about 5 rpms or greater, such as between about 10 rpms and about 50 rpms.

In one embodiment, a high rotational speed polishing process may be used. The high rotational speed process includes rotating the polishing medium 105 at a platen speed of about 150 rpm or greater, such as between about 150 rpm and about 750 rpm; and the substrate 113 may be rotated at a rotational speed between about 150 rpm and about 500 rpm, such as between about 300 rpm and about 500 rpm. Further description of a high rotational speed polishing process that may be used with the polishing articles, processes, and apparatus described herein is disclosed in U.S. patent application Ser. No. 60/308,030, filed on Jul. 25, 2001, and entitled, “Method And Apparatus For Chemical Mechanical Polishing Of Semiconductor Substrates.” Other motion, including orbital motion or a sweeping motion across the substrate surface, may also be performed during the process.

When contacting the substrate surface, a pressure of about 6 psi or less, such as about 2 psi or less, is applied between the polishing article 205 and the substrate surface. A pressure of about 2 psi or less, such as about 0.5 psi or less, is generally used with a substrate containing a low dielectric constant material.

FIG. 3 shows one embodiment of a polishing station 300, which may be representative of the polishing station 100 described above. Accordingly, like numerals have been used to designate like components described above with reference to FIG. 1 and FIG. 2. In general, such like components include the basin 102, the polishing head 130, the substrate 113, one electrode 104, the shaft 112, the perforated pad support disc 106, the polishing medium 105 and the conducting element 202 (which forms the second electrode).

The polishing station 300 is energized by one or more power supplies, such as power supply 302. In one embodiment, the power supply 302 is a direct current (DC) power supply. However, the power supply 302 may also be an alternating current (AC) power supply. In one aspect, a DC power supply is preferred to avoid alternately removing and depositing material on a substrate. The power supply 302 is particularly adapted to apply voltage or current flow through the electrolyte 120. To this end, the power supply 302 is connected by a positive (+) terminal to a first electrode and by a negative (−) terminal to a second electrode. In one embodiment, the first electrode is a conducting portion of the polishing medium 105, such as the conducting element 202. As a result, the first electrode is in direct contact with a substrate disposed on the polishing medium 105, at least during part of a polishing cycle. The second electrode is the counter electrode 104 disposed on a floor of the basin 102, for example. In contrast to the first electrode, the second electrode may not be in direct physical contact with the substrate.

In general, the application of the bias may be used to dissolve or remove conductive material, such as copper-containing materials, formed on a substrate surface. In one embodiment, the power supply 302 is capable of providing power between about 0 Watts and 100 Watts, a voltage between about 0V and about 10V, and a current between about 0 amps and about 10 amps. However, the particular operating specifications of the power supply 302 may vary according to application. The bias may also produce a current density between about 0.1 milliamps/cm² and about 50 milliamps/cm², such as, about 0.1 amps to about 20 amps for a 200 mm substrate. The bias is generally provided to produce anodic dissolution of the conductive material from the surface of the substrates at a current density up to about 100 milliamps/cm² for 300 mm in diameter substrates.

Illustratively, the operation of the polishing system 300 is controlled by a control system 312. In one embodiment, the control system 312 includes a controller 314. The controller 314 is operably connected to each of the devices of the polishing system 300, including the power supply 302, the fluid delivery system 172, the motor 124 and the carrier head 130. The controller 314 may include a central processing unit (CPU) 342, memory 344, and support circuits 346. The CPU 342 may be one of any form of computer processor that can be used in an industrial setting for controlling various drives and pressures. The memory 344 is connected to the CPU 342. The memory 344, or computer-readable medium, may be one or more of readily available memory such as random access memory (RAM), read only memory (ROM), floppy disk, hard disk, or any other form of digital storage, local or remote. The support circuits 346 are connected to the CPU 342 for supporting the processor in a conventional manner. These circuits include cache, power supplies, clock circuits, input/output circuitry, subsystems, and the like.

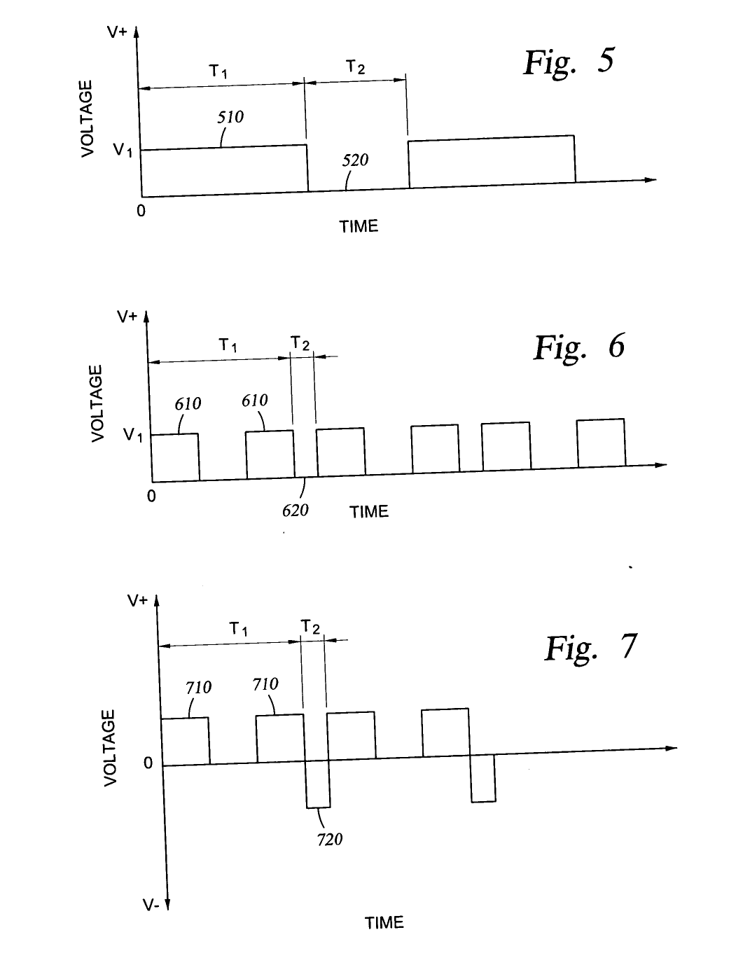

In one embodiment, the output of the power supply 302 is determined by the controller 312 according to, for instance, a software program 348 shown resident in memory 344. In this manner, the voltage signal provided by the power supply 302 to establish the potential difference and perform the electrochemical process may be varied depending upon the requirements for removing material from the substrate surface. For instance, a time-varying voltage signal may be provided to the conductive polishing medium 105. In one embodiment, a constant voltage signal 510 may initially be applied to the polishing medium 105 for a first time period T1, followed by a zero voltage signal 520 for a second time period T2, as shown in FIG. 5. This pattern may have a single cycle or any number of cycles as determined by the controller 312. For example, the voltage signal 510 may range from about 0.5 V to about 8 V, while the first time period T1 may range from 0 to about 15 seconds, and the second time period T2 may range from about 1 second to about 10 seconds.

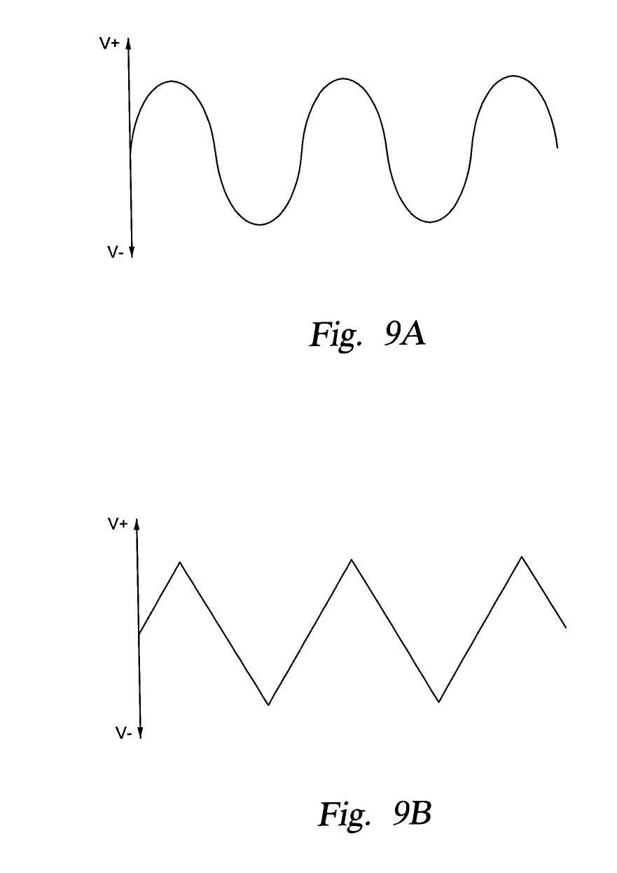

In another embodiment, the voltage signal pattern above may also be applied using electrical pulse modulation techniques. Using the electrical pulse modulation technique, a waveform of a voltage signal 610 may be applied for a first time period T1, followed by a zero voltage signal 620 for a second time period T2, as shown in FIG. 6. This pattern may have a single cycle or any number of cycles as determined by the controller 312. The voltage signal 610 may range from about 0.5 V to about 8 V, for example, while the first time period T1 may range from about 1 second to about 15 seconds and the second time period T2 may range from about 1 millisecond to about 5 seconds. Although a square waveform is illustrated in the figures, the invention contemplates other types of waveforms, such as sinusoidal (see FIG. 9A) and saw tooth (see FIG. 9B).

In yet another embodiment, instead of applying a zero voltage during the second time period T2, a waveform of a voltage signal with negative polarity may be applied. FIG. 7 illustrates a waveform of a voltage signal 710 being applied during a first time period T1, followed by a waveform of a voltage signal 720 with negative polarity during a second time period T2. For example, the voltage signal 710 may range from about 0.5 V to about 8 V, while the voltage signal 720 may range from about −0.5 V to about −8 V.

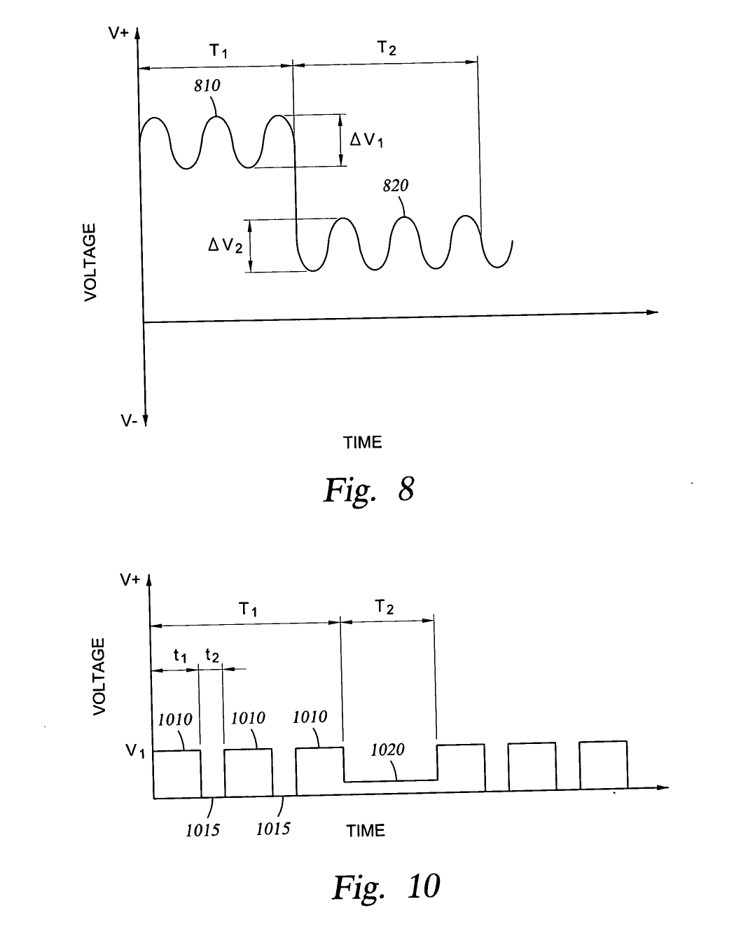

In still another embodiment, a modulated voltage signal 810 may be applied for a first time period T1, followed by a modulated voltage signal 820 for a second time period T2, as shown in FIG. 8. The modulate voltage signal 810 may be within a first range, i.e., delta V1, while the modulated voltage signal 820 may be within a second range, i.e., delta V2. This pattern may have a single cycle or any number of cycles as determined by the controller 312.

During the initial stages of the polishing process, a relatively high voltage signal may be applied to promote relatively aggressive removal or dissolution of the conductive material so as to reduce overall processing time and to increase throughput. In one embodiment, a lower (or ramp-up) voltage signal may be applied prior to applying the high voltage to remove contamination from the substrate surface. At the later stages of the polishing process, the low or zero voltage signal may be applied when the surface of a barrier layer (which is generally deposited between the substrate and the conductive material) is about to be exposed. The polishing process may be stopped when the barrier layer is substantially removed. The low or zero voltage signal may be applied, therefore, to eliminate or substantially reduce static etching, dishing, corrosion, erosion and burn marks, which may be caused by inefficient removal of the passivation layer. That is, application of the low or zero voltage signal allows the additives in the electrolyte to be replenished at the substrate surface and to allow process by-products to be removed from adjacent the substrate surface. Accordingly, application of the low or zero voltage signal allows current to be distributed more uniformly at the substrate surface.

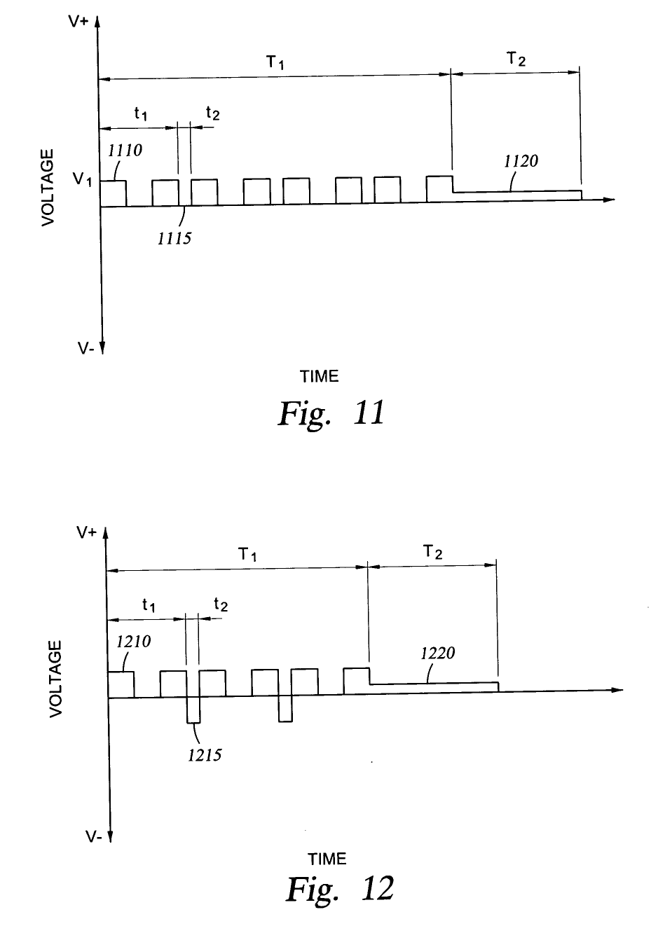

The invention contemplates that the amplitude of the voltage signal and the time periods may be varied in accordance to the particular metal(s) to be polished/planarized and the thicknesses thereof. A constant voltage signal may be applied with any of the above-described patterns for a first time period, followed by a lower constant voltage signal for a second time period. In one embodiment, a constant voltage signal 1010 is applied for a time period t1, followed by a zero voltage signal 1015 for a time period t2, with the cycle being repeated for a time period T1, and finally followed by a constant voltage signal 1020 for a time period of T2, as illustrated in FIG. 10. The constant voltage signal 1010 may range from about 4 V to about 8 V. Time period t1 may range from about 0 second to about 15 seconds. The constant voltage signal 1020 may range from 0 V to about 4 V. Time period t2 may range from about 1 second to about 10 seconds. Time period T1 and T2 may each range from about 1 second to 100 seconds. In another embodiment, a waveform of a voltage signal 1110 is applied for a time period t1, followed by a zero voltage signal 1115 for a time period t2, with the cycle being repeated for a time period T1, and finally followed by a constant voltage signal 1120 for a time period T2, as shown in FIG. 11. In yet another embodiment, a waveform of a voltage signal 1210 is applied for a time period t1, followed by a waveform of a voltage signal 1215 with negative polarity for a time period t2, with the cycle being repeated for a time period T1, and finally followed by a constant voltage signal 1220 for a time period T2, as shown in FIG. 12.

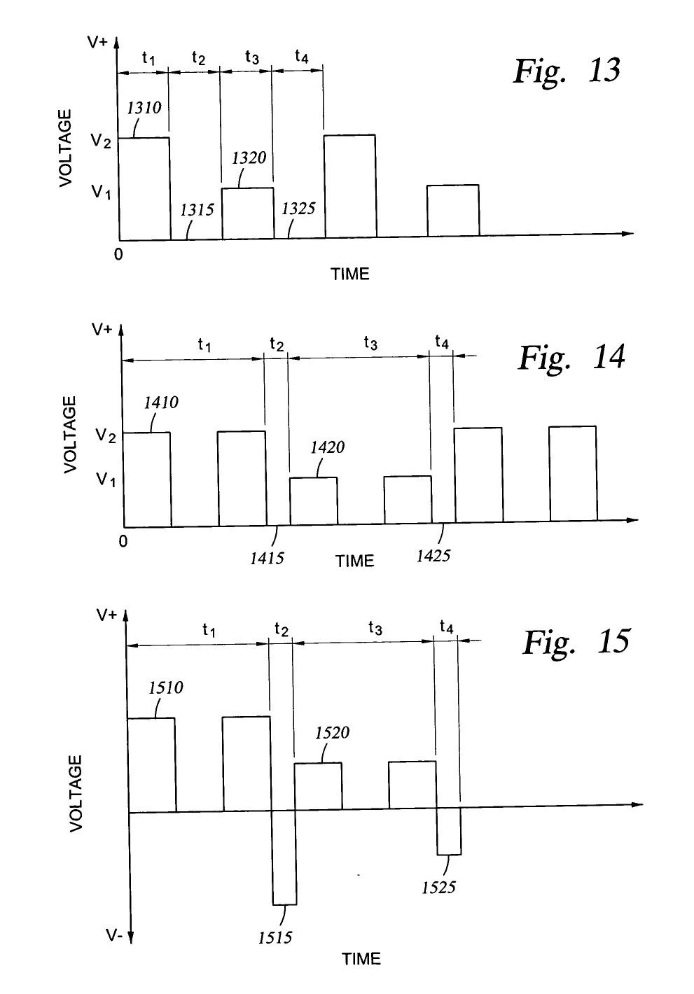

Alternatively, a first voltage signal may be applied with any of the above-referenced patterns, followed by a second voltage signal having a lower amplitude being applied with any of the above-described patterns. In one embodiment, a constant voltage signal 1310 is applied for a time period t1, followed by a zero voltage signal 1315 for a time period t2, followed by a constant lower voltage signal 1320 for a time period of t3, and followed by a zero voltage signal 1325 for a time period t4, as illustrated in FIG. 13. The voltage signal 1310 may range from about 4 V to about 8 V. The time periods t1 and t3 may each range from about 0 second to about 15 seconds. The voltage signal 1320 may range from about 0 V to about 4 V. The time periods t2 and t4 may each range from about 1 second to about 10 seconds. In another embodiment, a waveform of a voltage signal 1410 may be applied for a time period t1, followed by a zero voltage signal for a time period t2, followed by a waveform of a voltage signal 1420 with a lower amplitude, and followed by a zero voltage signal 1425 for a time period t4, as illustrated in FIG. 14. In yet another embodiment, a waveform of a voltage signal 1510 may be applied for a time period t1, followed by a waveform of a voltage signal 1515 with negative polarity for a time period t2, followed by a waveform of a voltage signal 1520 with a lower amplitude, and followed by a waveform of a voltage signal 1525 with negative polarity for a time period t4, as illustrated in FIG. 15.

As illustrated above, various permutations of the amplitude of the voltage signal and time periods may be made in accordance with an embodiment of the present invention. In some cases, the voltage signal amplitude may be varied as a polishing endpoint is detected. In accordance with an embodiment the invention, “endpoint” refers to a point in time during a polishing cycle at which sufficient bulk metal has been removed from a substrate.

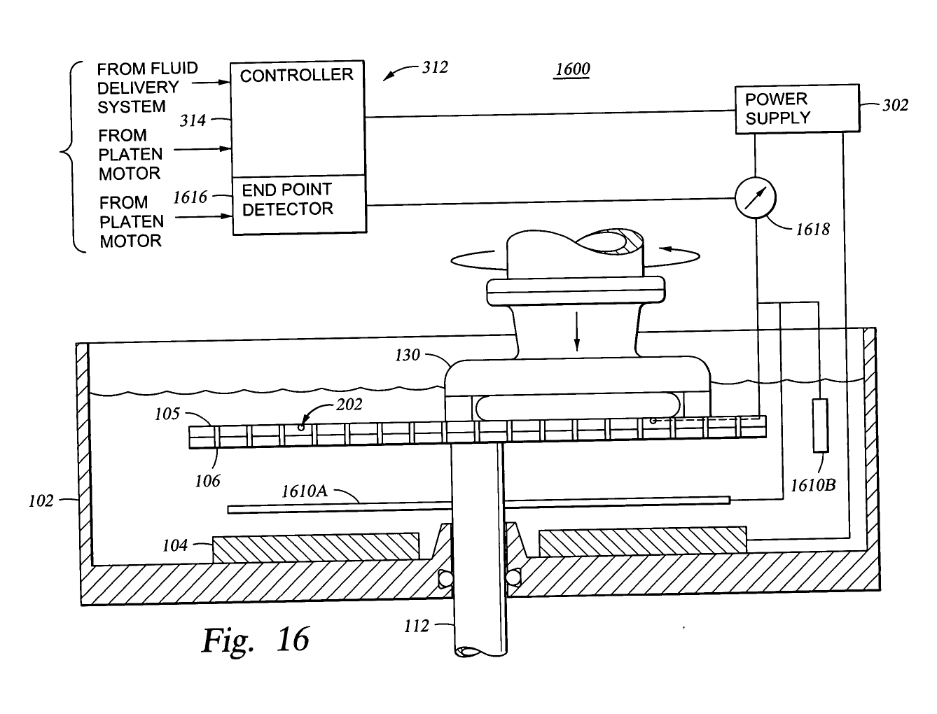

A polishing station 1600 with an endpoint detection mechanism will now be discussed with reference to FIG. 16. The polishing station 1600 is a representative of the polishing station 100 described above. Accordingly, like numerals have been used to designate like components described above with reference to FIG. 1 and FIG. 3. In general, such like components include the basin 102, the polishing head 130, the substrate 113, one electrode 104, the stem 112, the perforated pad support disc 106, the polishing medium 105 and the conducting element 202 (which forms the second electrode).

In one embodiment, the polishing station 1600 includes a reference electrode. For example, a reference electrode 1610A may be disposed between the disc 106 and the counter electrode 104. More generally, a reference electrode may be at any location in the basin as long as the reference electrode is submerged within the electrolyte 120. For example, a reference electrode 1610B is shown suspended between a sidewall of the basin 102 and the polishing medium 105. The reference electrode facilitates the maintenance of a constant electrochemical potential on the substrate. Accordingly, the provision of the reference electrode makes the removal rate independent from the changes in the conductivity in the current loop, which may caused by the deposition of poorly adhering copper on the counter electrode 104 (cathode) for instance. The reference electrode may be made of a very thin metal wire, such as a wire made of platinum, and is connected to the power supply 302.

The operation of the polishing system 1600 is controlled by a control system 312. In one embodiment, the control system 312 includes a controller 314 and an endpoint detector 1616. The controller 314 is operably connected to each of the devices of the polishing system 1600, including the power supply 302, the fluid delivery system 172, the motor 124 and the carrier head 130. The endpoint detector 1616 is configured to monitor signal characteristics of the signal provided by the power supply 302. To this end, the endpoint detector 1616 may be electrically connected to a meter 1618 disposed in a power line of the power supply 302. Although shown separately from the power supply 302, the meter 1618 may be an integral part of the power supply 302. In one embodiment, the meter 1618 is an amp meter configured to measure current. In another embodiment, the meter 1618 is a voltage meter configured to measure voltage. In still another embodiment, the meter is configured to measure voltage and current. A reading taken from the meter 1618 may then be used by the endpoint detector 1616 to determine whether a criterion has been satisfied. One criterion is whether the substrate has been sufficiently polished (i.e., whether a polishing endpoint has been reached). If a polishing endpoint has been reached, the endpoint detector 1616 may notify the controller 314, which may then issue one or more control signals to initiate additional steps and/or halt the polishing of the substrate.

Persons skilled in the art will recognize that the foregoing embodiments are merely illustrative. The invention contemplates and admits of many other embodiments. For example, a number of the foregoing embodiments described a face down electropolishing technique. That is, the substrate to be processed is in a face down orientation relative to the polishing pad. However, in other embodiments, face up electropolishing techniques are employed. These and other embodiments are considered within the scope of the invention.

While the foregoing is directed to embodiments of the present invention, other and further embodiments of the invention may be devised without departing from the basic scope thereof, and the scope thereof is determined by the claims that follow.

What is claimed is:

1. A method of electrochemically and mechanically planarizing a surface of a substrate, comprising:
(a) providing a basin containing an electrically conductive solution and an electrode disposed therein;
(b) disposing a polishing medium in the electrically conductive solution;
(c) positioning a substrate against the polishing medium so that a surface of the substrate contacts the electrically conductive solution;
(d) applying a first potential between the polishing medium and the electrode for a first time period; and
(e) applying a second potential between the polishing medium and the electrode for a second time period.

2. The method of claim 1, wherein the second potential is a zero potential.

3. The method of claim 1, wherein the second potential is lower than the first potential.

4. The method of claim 1, wherein the first potential is a pulsed potential with a waveform.

5. The method of claim 1, wherein the first potential is a pulsed potential with a waveform and the second potential is a pulsed potential with a waveform.

6. The method of claim 1, wherein the first potential is a pulsed potential with a waveform and the second potential is a pulsed potential with a waveform and a negative polarity.

7. The method of claim 1, wherein the first potential is a pulsed potential with a waveform and the second potential is a zero potential.

8. The method of claim 1, wherein the first potential is modulated within a predefined range of potentials.

9. The method of claim 1, wherein the second potential is modulated within a predefined range of potentials.

10. The method of claim 1, further comprising repeating steps (d) and (e) for a third time period.

11. The method of claim 1, wherein applying the first potential comprises:
applying a third potential between the polishing medium and the electrode for a third time period; and
applying a fourth potential between the polishing medium and the electrode for a fourth time period.

12. The method of claim 11, wherein the third potential is a pulsed potential with a waveform and the fourth potential is a pulsed potential with a waveform.

13. The method of claim 1, wherein applying the second potential comprises:
applying a third potential between the polishing medium and the electrode for a third time period; and
applying a fourth potential between the polishing medium and the electrode for a fourth time period.

14. The method of claim 13, wherein the third potential is a pulsed potential with a waveform and the fourth potential is a pulsed potential with a waveform.

15. The method of claim 1, wherein the first time period is greater than the second time period.

16. The method of claim 1, further comprising applying a third potential between the polishing medium and the electrode for a third time period.

17. The method of claim 16, wherein the third potential is a pulsed potential with a waveform.

18. The method of claim 16, wherein the first potential is a pulsed potential with a waveform, the second potential is a pulsed potential with a waveform, and the third potential is a pulsed potential with a waveform.

19. The method of claim 1 further comprising
(f) applying a third potential between the polishing medium and the electrode for a third time period; and
repeating steps (d) through (f) for a period of time.
